(19) United States
(12) Patent Application Publication
(10) Pub. No.: US 2014/0197518 A1
(43) Pub. Date: Jul. 17, 2014

(54) STACKED STRUCTURE SEMICONDUCTOR DEVICE

(71) Applicant: STMicroelectronics S.r.l., Agrate Brianza (IT)

(72) Inventors: Vittorio Giuseppe Maiorana, Gravina (IT); Alessandro Rizzo, Savoca (ME) (IT)

(73) Assignee: STMicroelectronics S.r.l., Agrate Brianza (IT)

(21) Appl. No.: 14/154,246

(22) Filed: Jan. 14, 2014

(30) Foreign Application Priority Data
Jan. 17, 2013 (IT) MI2013A000060

(51) Int. Cl. H01L 49/02

(52) U.S. Cl. CPC H01L 28/20; H01L 28/40
USPC 257/532; 438/382

(57) ABSTRACT

A semiconductor device includes a capacitor formed in a semiconductor substrate of a first conductivity type. The capacitor includes: a heavily-doped layer of a second conductivity type placed over the substrate, a first insulating layer placed over the heavily-doped layer of the second conductivity type, and a first metal layer placed over the first insulating layer. The semiconductor device further includes comprises a second insulating layer deposited over the capacitor and at least one resistor formed over the second insulating layer. The resistor includes a layer of a resistive material region arranged between two regions of a second metal layer.

### PRIORITY CLAIM

This application claims priority from Italian Application for Patent No. MI2013A000060 filed Jan. 17, 2013, the disclosure of which is incorporated by reference.

### TECHNICAL FIELD

The present disclosure relates to a stacked structure semiconductor device.

### BACKGROUND

In integrated electronic application market, where smaller packages are always needed, is more difficult to supply such a request, particularly using low-cost technologies with low-cost photo-techniques. To meet said requirement stacked structure techniques, whereby electric components are formed on different plans separated by intermediate insulating layers, could be adopted.

Semiconductor stacked structure techniques need the planarity of the intermediate insulating layer, an aspect which is always ensured in expensive advanced planar technologies. The planarity of said layer is a necessary condition for a stacking component to not suffer of structural defects which could limit the functionality.

A known low-cost technology, performed mainly for forming design and layout of products concerning linear regulators, is the HBIP40 (High Bipolar 40V) technology. The HBIP40 technology is a modular technology as it is possible to add to the basic process other different process steps, thus appearing suitable for stacking components. However, since HBIP40 technology is a not particularly advanced technology, the use of a planar insulating layer is not provided.

### SUMMARY

One aspect of the present disclosure is to provide to a stacked structure semiconductor device for limiting the occupation of semiconductor area.

One aspect of the present disclosure is a semiconductor device comprising a capacitor formed in a substrate of a first conductivity type. The capacitor comprises: a heavily-doped layer of a second conductivity type placed over said substrate, a first insulating layer placed over said heavily-doped layer of the second conductivity type, and a first metal layer placed over said first insulating layer. The semiconductor device comprises: a second insulating layer deposited over the capacitor, wherein at least one resistor is formed over said second insulating layer by means of a layer comprising at least a resistive material region arranged between two regions of a second metal layer.

### BRIEF DESCRIPTION OF THE DRAWINGS

The features and advantages of the present disclosure will be apparent from the following detailed description of its practical embodiments, shown by way of non-limiting example in the accompanying drawings, wherein:

FIG. 1 shows a schematic cross section of a multilayer semiconductor structure;

FIG. 2 shows a schematic cross section of a semiconductor structure device;

FIG. 3 shows a schematic layout of an integrated linear regulator;

FIG. 4 shows a schematic layout of an integrated linear regulator with the semiconductor structure device in FIG. 2.

### DETAILED DESCRIPTION OF THE DRAWINGS

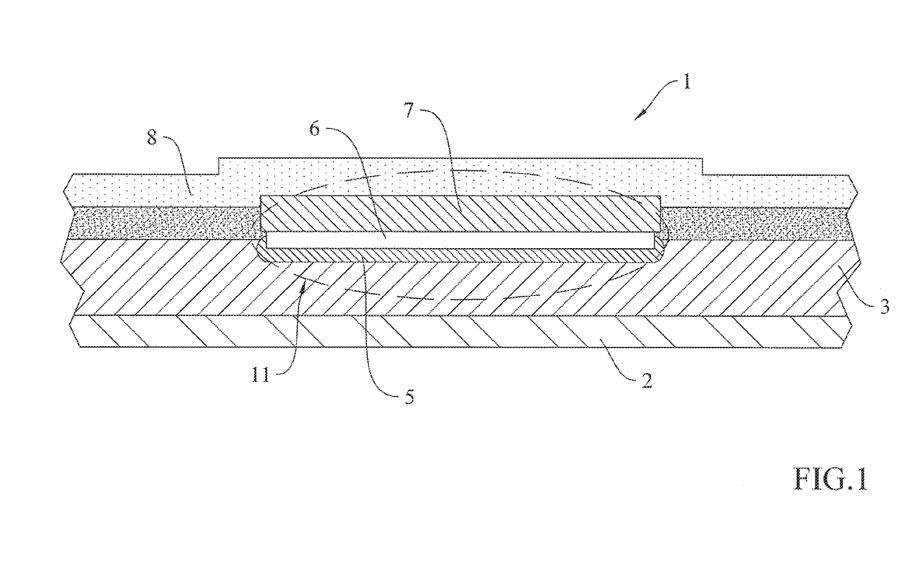

With reference to FIG. 1, a schematic cross section of a semiconductor structure 1 is shown. The semiconductor structure 1 is for example a multilayer semiconductor structure adopted in integrated linear regulator applications, for example a multilayer structure formed in HBIP40 (High Bipolar 40V) technology.

Said multilayer structure 1 comprises a semiconductor substrate 2 of a first conductivity type, for example a p-type semiconductor substrate. A capacitor 11 is formed over the semiconductor substrate 2; the capacitor 11 is formed by means a heavily-doped layer 5 of a second conductivity type, a first insulating layer 6 superimposed on the highly-doped layer 5 and a first metal layer 7 placed over said insulating layer 6. Preferably a lightly-doped layer 3 of a second conductivity type is formed on the semiconductor substrate 2, for example a lightly-doped n-type semiconductor epitaxial layer grown over said substrate 2. The second conductivity type heavily-doped layer 5 is preferably a heavily-doped n-type well obtained into the second conductivity type layer 3 and preferably, the first insulating layer 6 is a thermal Silicon dioxide (SiO₂) layer, placed over said heavily-doped n-type well 5 and under the first metal layer 7. In said capacitor 11 the heavily-doped well 5 and the first metal layer 7 are two parallel conductors of the capacitor while the insulating layer 6 is the dielectric layer placed between the conductors 5 and 6.

A second insulating layer 8, for example a buried Silicon dioxide (SiO₂) layer, is placed over said capacitor 11 and provides the electric insulation of the capacitor 11. The portion of surface over the capacitor 11 is surely planar because the dielectric layer 6 placed between the two conductors 5 and 6 of the capacitor ensures the planarity of the insulating layer 8.

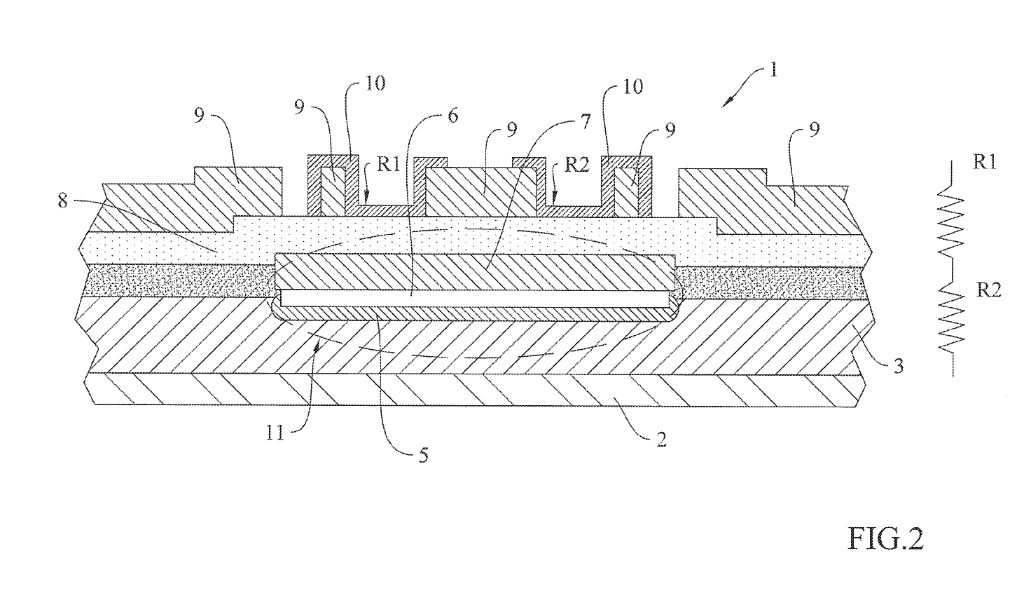

With reference to FIG. 2, at least one resistor is formed over said second insulating layer 8 by means of a layer comprising at least a region 10 of a resistive material, for example a Thin Film Resistor layer (TFR), arranged between two regions of a second metal layer 9. The region 10 of the resistive material is adjacent or at least partially adjacent to the regions 9 of the second metal layer and is adjacent to the insulating layer 8. In FIG. 2, for example, two resistors R1, R2 are shown, formed over the insulating layer placed on the capacitor 11. Said two resistances can be used to form a resistive divider.

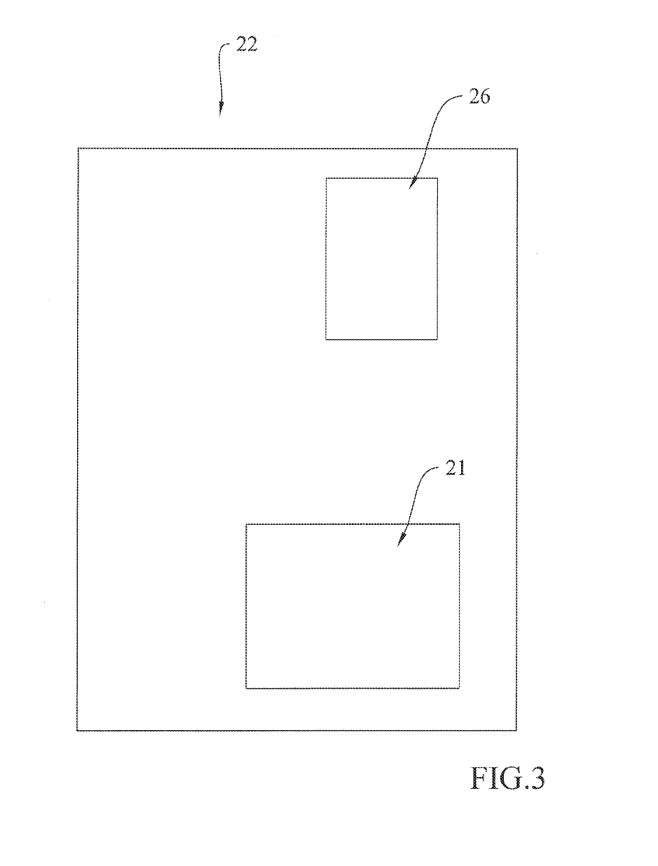

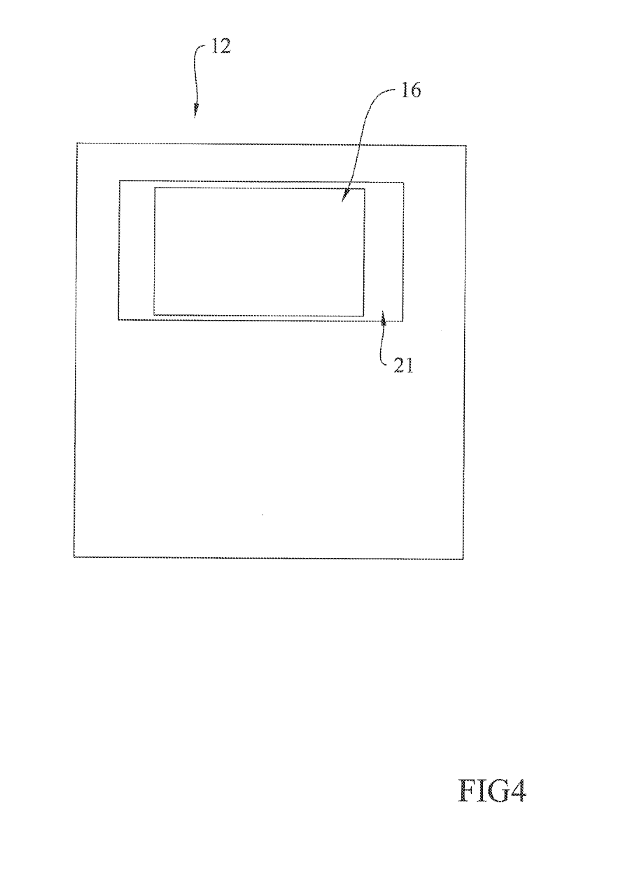

In fact, in linear regulator applications a resistive divider is needed and it requires an appropriate area of substrate. In the schematic layout of a conventional integrated linear regulator 22 shown in FIG. 3, for example, a resistive divider 26 is placed in a dedicated area and a capacitor 21 is formed in another dedicated area of the integrated linear regulator. Instead, in accordance with an embodiment, stacking the resistive divider over the capacitor 11 even in this kind of low cost technologies, a linear regulator occupies a lower semiconductor area. FIG. 4 shows schematically a layout of an integrated linear regulator 12 in which a resistor divider 16 is stacked over the capacitor 11 according to the present disclosure.

A method for manufacturing the semiconductor device 1 comprises the manufacturing of the capacitor 11 over a semiconductor substrate 2 of a first conductivity type by:
forming a heavily-doped layer 5 of a second conductivity type over the semiconductor substrate 2 of a first conductivity type,
forming a first insulating layer 6 over the heavily-doped layer 5 of the second conductivity type;
forming a first metal layer 7 over the first insulating layer 6.

The method comprises also depositing a second insulting layer 8 over the capacitor 11 and performing at least one resistor by:
depositing a second metal layer over the insulating layer 8,
selectively removing by photo-masking and photo-dry-etch process the second metal layer for forming at least two regions 9 of the second metal layer which are separated by a region without metal material,
depositing a resistive material layer for forming at least one region 10 of resistive material over said second insulating layer between said two regions 9 of the second metal layer.

Preferably, before the formation of the capacitor 11, a lightly-doped epitaxial semiconductor layer 3 of the second conductivity type is grown on the semiconductor substrate 2 of the first conductivity type; then the heavily-doped layer 5 is formed by forming a well in said lightly-doped epitaxial semiconductor layer 3 of the second conductivity type.

Preferably the second insulating layer 6 is a thermal Silicon dioxide layer which is thermally grown on the well 5 of the second conductivity type.

Preferably the resistive material of the region 10 is a Thin Film Resistor (TFR).

What is claimed is:

1. A semiconductor device, comprises:
a capacitor formed in a semiconductor substrate of a first conductivity type, said capacitor comprising:
a heavily-doped layer of a second conductivity type placed over said substrate,
a first insulating layer placed over said heavily-doped layer of the second conductivity type, and
a first metal layer placed over said first insulating layer,
a second insulating layer deposited over the capacitor, and
at least one resistor is formed over said second insulating layer using a layer comprising at least a resistive material region arranged between two regions of a second metal layer.

2. The semiconductor device according to claim 1, wherein said heavily-doped layer is a well obtained in a lightly-doped epitaxial semiconductor layer of the second conductivity type grown on the semiconductor substrate of the first conductivity type .

3. The semiconductor device according to claim 1, wherein said first insulating layer is a thermal Silicon dioxide layer.

4. The semiconductor device according to claim 1, wherein said resistive layer is a Thin Film Resistor (TFR) layer.

5. An integrated device, comprising:
a circuit including a resistor and a capacitor;
wherein the resistor is stacked on top of the capacitor.

6. The integrated device of claim 5, wherein the capacitor is formed in a semiconductor substrate of a first conductivity type and comprises:
a heavily-doped layer of a second conductivity type placed over said substrate,
a first insulating layer placed over said heavily-doped layer of the second conductivity type, and
a first metal layer placed over said first insulating layer.

7. The integrated device of claim 5, wherein the resistor is formed over a semiconductor substrate and comprises an insulating layer deposited over the substrate, and a resistive material region arranged between two regions of a metal layer.

8. The integrated device of claim 5, wherein the capacitor includes a flat metal electrode formed over a semiconductor substrate and wherein the resistor includes a resistive material region formed over an insulating layer which is deposited on top of the flat metal electrode of the capacitor.

9. The integrated device of claim 8, wherein the capacitor further includes an additional electrode formed of a buried doped semiconductor material formed in said substrate.

10. A method, comprising:
manufacturing a capacitor over a semiconductor substrate of a first conductivity type, said capacitor being manufactured by:
forming a heavily-doped layer of a second conductivity type over said semiconductor substrate of a first conductivity type,
forming a first insulating layer over the heavily-doped layer of the second conductivity type, and
forming a first metal layer over the first insulating layer;
depositing a second insulting layer over the capacitor; and
forming at least one resistor by:
depositing a second metal layer over said insulating layer,
selectively removing the second metal layer for forming at least two regions of the second metal layer which are separated by a region without metal material, and
depositing a resistive material layer for forming at least one region of resistive material over said second insulating layer an between said two regions of the second metal layer.

11. The method according to claim 10, further including, before forming the capacitor, growing a lightly-doped epitaxial semiconductor layer of the second conductivity type on the semiconductor substrate of the first conductivity type, and forming said heavily-doped layer as a well formed in said lightly-doped epitaxial semiconductor layer of the second conductivity type.

12. The method according to claim 10, wherein said first insulating layer is a thermal Silicon dioxide layer.

13. The method according to claim 10, wherein said resistive layer is a Thin Film Resistor (TFR) layer.
